(19) United States
(12) Patent Application Publication
(10) Pub. No.: US 2025/0107301 A1
(43) Pub. Date: Mar. 27, 2025

(54) LIGHT EMITTING DEVICE

(71) Applicant: TOYODA GOSEI CO., LTD., Kiyosu-shi (JP)

(72) Inventors: Hiroaki MAKINO, Kiyosu-shi (JP); Hideki OMOYA, Kiyosu-shi (JP); Shinichi MATSUI, Kiyosu-shi (JP); Koichi MIZUTANI, Kiyosu-shi (JP)

(21) Appl. No.: 18/886,190

(22) Filed: Sep. 16, 2024

(30) Foreign Application Priority Data
Sep. 21, 2023 (JP) 2023-155697

(51) Int. Cl. H01L 33/62; C22C 21/12; H01L 23/00; H01L 33/48

(52) U.S. Cl. CPC H10H 20/857; C22C 21/12; H01L 24/45; H10H 20/8506; H01L 2224/45123; H01L 2224/45124; H01L 2224/45147; H01L 2924/12041

(57) ABSTRACT

A light emitting device includes: a light emitting element containing a group III nitride and configured to emit ultraviolet light; and a bonding wire electrically connected to the light emitting element, and the bonding wire contains at least one selected from the group consisting of: an alloy containing Al as a main component and containing Cu; an alloy containing Mg as a main component and containing Cu; Mg; and an alloy containing Mg, or includes a first layer containing Cu or an alloy containing Cu, and a second layer containing one selected from the group consisting of: Al; an alloy containing Al; Mg; and an alloy containing Mg.

### CROSS-REFERENCE TO RELATED APPLICATION

This application is based on and claims priority under 35 USC 119 from Japanese Patent Application No. 2023-155697 filed on Sep. 21, 2023.

### TECHNICAL FIELD

The present invention relates to a light emitting device.

### BACKGROUND ART

A wavelength of ultraviolet light from a solid-state light emitting element using a group III nitride semiconductor corresponds to a wavelength band in a range of about 210 nm to 400 nm. In particular, it is known that UVC (wavelength: 100 nm to 280 nm) can efficiently sterilize and eliminate bacteria, and there is an increasing demand for a group III nitride semiconductor light emitting element that emits ultraviolet light having an emission wavelength corresponding to that of the UVC. The ultraviolet light emitting element has a structure in which an AlN layer is formed on a sapphire substrate, and an n-type layer, an active layer, and a p-type layer made of AlGaN are stacked on the AlN layer.

In a light emitting device in which a light emitting element for ultraviolet light emission is mounted on a mounting substrate, electrical connection is made using bonding wires. JP2018-49949A describes that Al is used as a bonding wire in a light emitting device for ultraviolet light emission.

### SUMMARY OF INVENTION

Since the light extraction efficiency of the light emitting element for ultraviolet light emission is lower than that of a light emitting element for visible light emission, there is a greater demand for improving the light extraction efficiency for ultraviolet light than for visible light. Depending on the material of a bonding wire used in a light emitting device, ultraviolet light emitted by a light emitting element may be absorbed, which may cause a decrease in the light extraction efficiency. Therefore, in a light emitting device, it is preferable to use Al, which has a high reflectance, for the bonding wire from the viewpoint of light extraction efficiency.

However, since Al is prone to electromigration, when Al is used as a bonding wire, there is a possibility that the bonding wire may suffer a breakage failure due to electromigration, which poses problems in terms of life span or reliability.

The present invention has been made in view of the above background, and an object of the present invention to provide a light emitting device for ultraviolet light emission having a structure with excellent resistance to electromigration while maintaining high light extraction efficiency by using a bonding wire made of a material having high reflectance.

An aspect of the present invention is directed to a light emitting device including:
a light emitting element containing a group III nitride and configured to emit ultraviolet light; and
a bonding wire electrically connected to the light emitting element,
wherein the bonding wire
contains at least one selected from the group consisting of: an alloy containing Al as a main component and containing Cu; an alloy containing Mg as a main component and containing Cu; Mg; and an alloy containing Mg, or
includes a first layer containing Cu or an alloy containing Cu, and a second layer containing one selected from the group consisting of: Al; an alloy containing Al; Mg; and an alloy containing Mg.

According to the aspect of the present invention, a bonding wire forming a light emitting device contains at least one selected from the group consisting of an alloy containing Al as a main component and containing Cu, an alloy containing Mg as a main component and containing Cu, Mg, and an alloy containing Mg, or includes a first layer made of Cu or an alloy containing Cu, and a second layer made of one selected from the group consisting of Al, an alloy containing Al, Mg, and an alloy containing Mg. Therefore, high reflectance can be obtained. Accordingly, high light extraction efficiency of ultraviolet light can be obtained. Further, by forming the bonding wire from the above material, electromigration resistance can be improved and breakage failures and the like can be reduce as compared to the case where Al is used, resulting in an improved life span and increased reliability.

As described above, according to the above aspect, it is possible to provide a light emitting device for ultraviolet light emission having a structure with excellent resistance to electromigration while maintaining high light extraction efficiency by using a bonding wire made of a material having high reflectance.

### BRIEF DESCRIPTION OF DRAWINGS

FIG. 1 is a cross-sectional view showing a configuration of a light emitting device according to a first embodiment.

FIG. 2 is an enlarged cross-sectional view of a light emitting element forming the light emitting device according to the first embodiment.

FIG. 3 is a graph showing results of Experiment 1, illustrating the relationship between an emission wavelength and reflectance of a reflective layer.

FIG. 4 is a graph showing results of Experiment 2, illustrating the relationship between a thickness of a p-side contact electrode (ITO) and transmittance of ultraviolet light having a wavelength of 280 nm.

### DETAILED DESCRIPTION OF THE INVENTION

As described above, a light emitting device includes: a light emitting element emitting containing a group III nitride and configured to emit ultraviolet light; and a bonding wire electrically connected to the light emitting element. The bonding wire contains at least one selected from the group consisting of an alloy containing Al as a main component and containing Cu, an alloy containing Mg as a main component and containing Cu, Mg, and an alloy containing Mg, or includes a first layer made of Cu or an alloy containing Cu, and a second layer made of one selected from the group consisting of Al, an alloy containing Al, Mg, and an alloy containing Mg.

Here, the alloy containing Al is not limited to an alloy containing Al as a main component, but includes an alloy containing Al but not containing Al as a main component. The alloy containing Mg is not limited to an alloy containing Mg as a main component, but includes an alloy containing Mg but not containing Mg as a main component. The alloy containing Cu is not limited to an alloy containing Cu as a main component, but includes an alloy containing Cu but not containing Cu as a main component.

In particular, of the bonding wire, a wire electrically connected to a p-side electrode of the light emitting element contains at least one selected from the group consisting of an alloy containing Al as a main component and containing Cu, an alloy containing Mg as a main component and containing Cu, Mg, and an alloy containing Mg, or includes a first layer made of Cu or an alloy containing Cu, and a second layer made of one selected from the group consisting of Al, an alloy containing Al, Mg, and an alloy containing Mg. Electromigration occurs significantly on the p-side electrode side. Therefore, by forming the wire connected to the p-side electrode from the above-mentioned material, it is possible to improve the electromigration resistance.

In the light emitting device, the light emitting element may include an electrode pad, and the bonding wire may be bonded to the electrode pad of the light emitting element. In this case, it is possible to increase the electromigration resistance of the bonding wire bonded to the electrode pad of the light emitting element.

In this configuration, the light emitting device may further include a mounting substrate having a mounting surface, the light emitting element is mounted on the mounting surface of the mounting substrate and is a face-up type having the electrode pad on a surface opposite to the mounting surface of the mounting substrate, and the bonding wire has one end bonded to the electrode pad of the light emitting element, and the other end bonded to the mounting substrate.

### First Embodiment

### 1. Configuration of Light Emitting Device 1

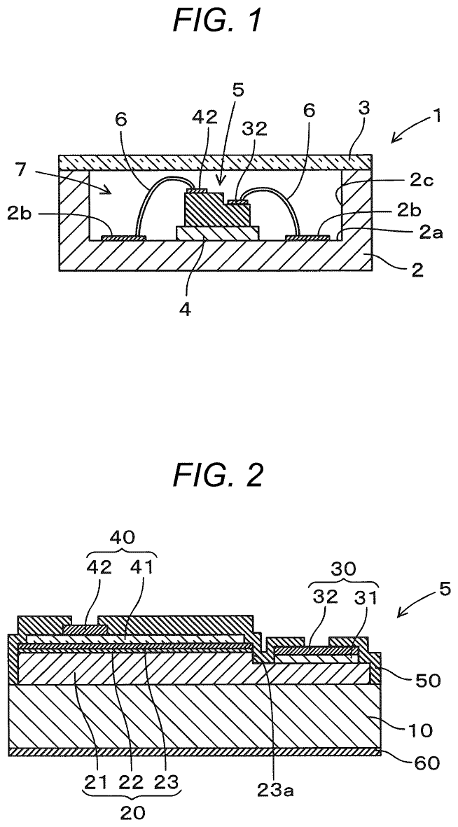

A configuration of a light emitting device 1 according to the embodiment will be described with reference to FIG. 1. The light emitting device 1 may be a light emitting element package that accommodates a light emitting element 5 as a main element, or may be a device that includes a driving circuit and the like in addition to the light emitting element 5.

The light emitting device 1 includes a mounting substrate 2, a sealing material 3, a submount 4, the light emitting element 5, and bonding wires 6. The light emitting device 1 may not include the submount 4, and may include a driving circuit (not shown) or the like.

The mounting substrate 2 has a mounting surface 2a, and is a substrate for mounting components such as the submount 4 and the light emitting element 5 on the mounting surface 2a. The mounting substrate 2 has a circuit pattern formed thereon, and has substrate electrode pads 2b to which the bonding wires 6 are bonded. In the present embodiment, the mounting substrate 2 has a recessed portion 2c, and the mounting surface 2a is on a bottom surface of the recessed portion 2c. The mounting substrate 2 may be a flat plate having no recessed portion 2c, and the mounting surface 2a is on one surface of the flat plate. A main body portion of the mounting substrate 2 is formed of, for example, ceramics such as AlN, Al₂O₃, SiC, and Si₂N₄.

The sealing material 3 forms an accommodation space 7 in which the submount 4, the light emitting element 5, the bonding wires 6, and the like can be accommodated between the sealing material 3 and the mounting substrate 2, and is made of a transparent material that transmits the ultraviolet light having the emission wavelength emitted by the light emitting element 5. The sealing material 3 may be made of any material that transmits the ultraviolet light having the emission wavelength, and may be made of, for example, quartz, sapphire, or the like. In the present embodiment, the sealing material 3 is formed in a flat plate shape, and a peripheral edge of one surface thereof is bonded to the mounting substrate 2. The sealing material 3 is not limited to a flat plate shape, and may be formed in a lens shape.

The submount 4 is mounted on the mounting surface 2a of the mounting substrate 2. A main body portion of the submount 4 is formed of, for example, ceramics such as AlN, Al₂O₃, SiC, Si₂N₄, Si₃N₄, and Al₂O₃/ZrO₂. Here, Al₂O₃/ZrO₂ means that Al₂O₃ and ZrO₂ are stacked in this order from the mounting substrate 2 side.

The light emitting element 5 contains a group III nitride, and emits ultraviolet light having a predetermined emission wavelength. The emission wavelength of the light emitting element 5 is 200 nm to 400 nm. The light emitting element 5 is disposed on the submount 4. That is, the light emitting element 5 is mounted on the mounting surface 2a of the mounting substrate 2 via the submount 4.

The light emitting element 5 is a face-up type element including electrode pads 32 and 42 on a surface opposite to the mounting surface 2a of the mounting substrate 2. Accordingly, the electrode pads 32 and 42 of the light emitting element 5 are positioned on the surface opposite to the mounting surface 2a of the mounting substrate 2, and are disposed to face an inner side surface of the sealing material 3 at a distance. An element substrate 10 of the light emitting element 5, which will be described later, is positioned on a side close to the mounting surface 2a of the mounting substrate 2. That is, the ultraviolet light emitted from the light emitting element 5 is emitted toward the electrode pads 32 and 42, passes through the sealing material 3, and is output to the outside.

One end of the bonding wire 6 is bonded to the electrode pad 32 or 42 of the light emitting element 5, and the other end is bonded to the substrate electrode pad 2b of the mounting substrate 2. Accordingly, the bonding wire 6 is electrically connected directly to the light emitting element 5.

The bonding wire 6 may be formed of a single material or may be formed of a plurality of layers, as described below.

The bonding wire 6 is formed of a single material, and contains at least one selected from the group consisting of an alloy containing Al as a main component and containing Cu, an alloy containing Mg as a main component and containing Cu, Mg, and an alloy containing Mg. Here, the alloy containing Mg is not limited to an alloy containing Mg as a main component, but includes an alloy containing Mg but not containing Mg as a main component. The alloy containing Mg is preferably an alloy containing Mg as a main component.

The alloy containing Al as a main component and containing Cu is preferably at least one selected from the group consisting of AlCu, AlSiCu, and AlCuSn. The alloy containing Mg is preferably at least one selected from the group consisting of AlZnMg, AlMgSi, and AlMg. That is, the alloy containing Mg preferably contains Al.

When the bonding wire 6 is formed of a plurality of layers, the bonding wire 6 has two or more layers formed of different materials. The bonding wire 6 is formed of a plurality of layers, and includes a first layer made of Cu or an alloy containing Cu, and a second layer made of one selected from the group consisting of Al, an alloy containing Al, Mg, and an alloy containing Mg. The first layer may form a central portion of the bonding wire 6 or may be formed on a surface layer of a base material forming the central portion. The second layer preferably forms a coating layer that coats an outer peripheral surface of the first layer. In this case, it is preferable that a cross-sectional area of a transverse section (radial cross section) of the first layer is larger than a cross-sectional area of a transverse section of the second layer.

The alloy containing Cu forming the first layer is not limited to an alloy containing Cu as a main component, but includes an alloy containing Cu but not containing Cu as a main component. The alloy containing Cu is preferably an alloy containing Cu as a main component. The alloy containing Cu is preferably at least one selected from the group consisting of AlCu, AlSiCu, and AlCuSn.

The alloy containing Al forming the second layer is not limited to an alloy containing Al as a main component, but includes an alloy containing Al but not containing Al as a main component. The alloy containing Al is preferably an alloy containing Al as a main component. The alloy containing Al is preferably at least one selected from the group consisting of AlCu, AlSiCu, and AlCuSn. The alloy containing Mg forming the second layer is not limited to an alloy containing Mg as a main component, but includes an alloy containing Mg but not containing Mg as a main component. The alloy containing Mg is preferably an alloy containing Mg as a main component. The alloy containing Mg is preferably at least one selected from the group consisting of AlZnMg, AlMgSi, and AlMg.

By forming the bonding wires 6 from the above-mentioned materials, it is possible to improve the electromigration resistance.

In particular, among the bonding wires 6, the wire connected to a p-side electrode 40 (described later) of the light emitting element 5 is preferably made from the above-described material. Electromigration occurs significantly on the p-side electrode 40 side. Therefore, by forming the bonding wire 6 connected to the p-side electrode 40 from the above-mentioned material, it is possible to improve the electromigration resistance. At this time, the bonding wire 6 connected to an n-side electrode 30 may be formed of the same material as the bonding wire 6 connected to the p-side electrode 40 or may be formed of a different material.

In this embodiment, the accommodation space 7 defined by the mounting substrate 2 and the sealing material 3 forms an air layer. Alternatively, the accommodation space 7 may contain an inactive compound that is liquid at normal temperature and pressure. The accommodation space 7 may be filled with a liquid inactive compound entirely, or the inactive compound may be placed in only a part of the accommodation space 7, including an opposing region between the light emitting element 5 and the sealing material 3, and the other part is air layer. The inactive compound may be, for example, a fluoride resin.

In the present embodiment, the light emitting device 1 is exemplified as having a configuration including the submount 4, but as described above, the light emitting device 1 may be formed without the submount 4. In this case, the light emitting element 5 is directly mounted on the mounting surface 2a of the mounting substrate 2.

### 2. Configuration of Face-Up Type Light Emitting Element 5

The configuration of the face-up type light emitting element 5 will be described with reference to FIG. 2. FIG. 2 is a diagram showing the configuration of the light emitting element 5, and is a cross-sectional view in a direction perpendicular to a substrate principal surface.

The light emitting element 5 includes the element substrate 10, a semiconductor layer 20, the n-side electrode 30, the p-side electrode 40, a protective layer 50, and a reflective layer 60. The light emitting element 5 is of a face-up type, that is, has a structure in which light is extracted from a surface (upper surface in FIG. 2) opposite to the element substrate 10. The light emitting element 5 is a light emitting element for ultraviolet light emission having an emission wavelength of 200 nm to 400 nm, and in particular, is a light emitting element for deep ultraviolet light emission having an emission wavelength of 200 nm to 280 nm (UVC band).

The element substrate 10 is, for example, a substrate made of sapphire. The plane orientation of the principal surface of the element substrate 10 is, for example, the a-plane or the c-plane. The element substrate 10 may have an off angle of 0.1 to 2 degrees in an m-axis direction. Other than sapphire, the element substrate 10 may be made of any material as long as the material has a high transmittance with respect to the emission wavelength and allows crystal growth of a group III nitride semiconductor. For example, the element substrate 10 may be an AlN substrate or an AlN template substrate in which an AlN layer is formed on a sapphire substrate.

The semiconductor layer 20 is formed on the principal surface of the element substrate 10 by crystal growth. The semiconductor layer 20 includes a group III nitride semiconductor. The semiconductor layer 20 includes at least an n-type layer 21, an active layer 22, and a p-type layer 23. The semiconductor layer 20 is formed by stacking the n-type layer 21, the active layer 22, and the p-type layer 23 in this order from the element substrate 10 side.

The n-type layer 21 is provided on the element substrate 10. The n-type layer 21 is formed of an n-type group III nitride semiconductor. The n-type layer 21 is made of, for example, n-AlGaN. An Al composition in the n-type layer 21 (the molar ratio of Al in the entire group III metal) is, for example, 60% to 90%. The n-type impurity in the n-type layer 21 is Si, and a Si concentration is, for example, 1×10¹⁸ cm⁻³ to 5×10¹⁹ cm⁻³. A thickness of the n-type layer 21 is, for example, 0.5 μm to 5 μm. A C concentration in the n-type layer 21 is 1×10¹⁵ cm⁻³ to 1×10¹⁹ cm⁻³.

The n-type layer 21 may include a plurality of layers. For example, the n-type layer 21 may be a superlattice layer in which AlGaN having different Al compositions are alternately stacked. Further, a base layer made of AIN may be provided between the element substrate 10 and the n-type layer 21. In addition, materials other than Si may be used as the n-type impurity.

The active layer 22 is provided on the n-type layer 21. The active layer 22 is formed of a group III nitride semiconductor. The active layer 22 has an SQW structure in which a barrier layer, a well layer, and a barrier layer are stacked in this order from the n-type layer 21 side. The active layer 22 may also have an MQW structure. In this case, the number of repetitions of the MQW structure is, for example, 2 to 10.

The well layer is made of AlGaN, and an Al composition therein is set according to a desired emission wavelength. A Si concentration in the well layer is, for example, 1×10¹⁸ cm⁻³ or less, and the well layer may be non-doped. A thickness of the well layer is, for example, 0.5 nm to 5 nm.

The barrier layer is made of AlGaN having an Al composition higher than that of the well layer, and the Al composition is, for example, 50% to 100%. A Si concentration in the barrier layer is, for example, 2×10¹⁹ cm⁻³ or less, and the barrier layer may be non-doped. A thickness of the barrier layer is, for example, 3 nm to 30 nm. The barrier layer may be AlGaInN having band gap energy larger than that of the well layer.

A hole blocking layer may be provided between the n-type layer 21 and the active layer 22. The hole blocking layer can prevent holes injected from the p-side electrode 40 from going beyond the active layer 22 and diffusing to the n-type layer 21 side. The hole blocking layer is made of AlGaN or AlN having an Al composition higher than that of the barrier layer of the active layer 22. A thickness of the hole blocking layer is, for example, one molecular layer to 2 nm. In the case of AlN, one molecular layer is about 0.26 nm.

The p-type layer 23 is provided on the active layer 22. The p-type layer 23 is formed of a group III nitride semiconductor. The p-type layer 23 forms a layer in contact with an electrode, and is therefore also called a p-type contact layer. The p-type layer 23 may be made of Mg-doped p-GaN or p-AlGaN. When the p-type layer 23 is made of p-AlGaN, an Al composition therein is, for example, 50% or less, preferably 30% or less.

When the p-type layer 23 is made of GaN, a thickness of the p-type layer 23 is preferably 1 nm or more and 50 nm or less. GaN may absorb the ultraviolet light emitted from the active layer 22, but can transmit the ultraviolet light if made sufficiently thin. Therefore, a large decrease in external quantum efficiency can be avoided. The thickness of the p-type layer 23 is preferably 1 nm or more and 10 nm or less. A Mg concentration in the p-type layer 23 is, for example, 1×10²⁰ cm⁻³ to 1×10²² cm⁻³.

The p-type layer 23 may include a plurality of layers having different Al compositions and Mg concentrations. When the p-type layer 23 includes a plurality of layers, an uppermost layer (p-type contact layer) in contact with a p-side contact electrode 41 is preferably made of p-GaN or AlGaN having a low Al composition. This is to reduce the contact resistance with the p-side contact electrode 41. In this case, the Al composition of the AlGaN having a low Al composition is 50% or less, preferably 30% or less. When the p-type layer 23 is made of AlGaN having an Al composition of 50% or less, the thickness thereof is preferably 20 nm or less. By sufficiently reducing the thickness, the ultraviolet light can be transmitted.

A groove 23a having a depth reaching the n-type layer 21 is formed in a partial region of the surface of the p-type layer 23. This groove 23a is for exposing the n-type layer 21 so as to provide the n-side electrode 30 therein.

An electron blocking layer may be provided between the active layer 22 and the p-type layer 23. The electron blocking layer can prevent electrons injected from the n-side electrode 30 from going beyond the active layer 22 and diffusing to the p-type layer 23 side. The electron blocking layer is formed of a group III nitride semiconductor. The electron blocking layer is made of AlGaN or AlN having an Al composition higher than that of the barrier layer of the active layer 22. The electron blocking layer may be doped with p-type impurities such as Mg, or may be non-doped. A thickness of the electron blocking layer is, for example, 1 nm to 20 nm.

A composition gradient layer may be provided between the electron blocking layer and the p-type layer 23. The composition gradient layer is formed of a group III nitride semiconductor. The composition gradient layer is a p-type layer formed by a method called polarization doping. That is, the composition gradient layer is a layer in which an Al composition changes in a thickness direction, and is set such that the Al composition is reduced as a distance from the electron blocking layer increases. The p-type layer 23 has an Al composition lower than the minimum Al composition of the composition gradient layer. It is difficult to increase a hole concentration in AlGaN having a high Al composition when doped with Mg, but the hole concentration can be increased by polarization doping, and the efficiency of injecting holes into the active layer 22 can be improved. In addition, since the polarization doping does not require doping with Mg, crystallinity can be improved.

The n-side electrode 30 is provided in contact with the n-type layer 21 exposed at a bottom surface of the groove 23a. The n-side electrode 30 includes an n-side contact electrode 31 and an n-side electrode pad 32 in a direction perpendicular to the principal surface of the element substrate 10. The n-side contact electrode 31 is provided in contact with the n-type layer 21 exposed on the bottom surface of the groove 23a. The n-side contact electrode 31 is made of V/Al/Ti, Ti/Al, V/Al, or the like. Here, A/B means that A and B are stacked in this order from a side on which the material is placed. For example, when the n-side contact electrode 31 is made of V/Al/Ti, V, Al, and Ti are stacked in this order from the n-type layer 21 side. A thickness of the n-side contact electrode 31 is 100 nm to 300 nm.

The n-side electrode pad 32 is provided in contact with the n-side contact electrode 31. The n-side electrode pad 32 is made of Ti/Ni/Au/Al, Ti/Pt/Au/Al, or the like. A thickness of the n-side electrode pad 32 is 300 nm to 600 nm.

The p-side electrode 40 is provided in contact with the p-type layer 23. The p-side electrode 40 includes the p-side contact electrode 41 and a p-side electrode pad 42.

The p-side contact electrode 41 is provided in contact with the p-type layer 23. The p-side contact electrode 41 is provided over an entire region of the element substrate 10 excluding a peripheral edge and the groove 23a. The p-side contact electrode 41 is set to transmit the ultraviolet light of the emission wavelength. The p-side contact electrode 41 is made of one type of oxide selected from the group consisting of ITO and IZO, or one type of metal selected from the group consisting of Ru, Rh, or an alloy containing these as main components, NiAu, and Mg. These materials can provide good contact with the p-type layer 23.

When the p-side contact electrode 41 is made of an oxide such as ITO or IZO, a thickness of the p-side contact electrode 41 is 40 nm or less, and preferably 20 nm or less. By setting the thickness of the p-side contact electrode 41 as described above, the transmittance of the ultraviolet light can be increased. Further, the p-side contact electrode 41 has a thickness of 1 nm or more, preferably 3 nm or more. By setting the thickness of the p-side contact electrode 41 as described above, it is possible to obtain a good contact with the p-type layer 23.

Further, when the p-side contact electrode 41 is made of a metal such as Ru, Rh, or an alloy containing these as main components, NiAu, and Mg, the thickness of the p-side contact electrode 41 is 10 nm or less, and preferably 4 nm or less. By setting the thickness of the p-side contact electrode 41 as described above, the transmittance of the ultraviolet light can be increased. Further, the p-side contact electrode 41 has a thickness of 1 nm or more, preferably 3 nm or more. By setting the thickness of the p-side contact electrode 41 as described above, it is possible to obtain a good contact with the p-type layer 23.

The p-side contact electrode 41 is preferably configured such that the transmittance for the ultraviolet light having a predetermined emission wavelength is 30% or more, and preferably 50% or more. For example, the p-side contact electrode 41 may be configured such that the transmittance for the ultraviolet light having a wavelength of 280 nm is 30% or more, and preferably 50% or more.

When the p-side contact electrode 41 is made of an oxide such as ITO or IZO, the transmittance for the ultraviolet light having a wavelength of 280 nm can be made 30% or more by setting the thickness of the p-side contact electrode 41 to 40 nm or less. When the thickness of the p-side contact electrode 41 is 20 nm or less, the transmittance for the ultraviolet light having a wavelength of 280 nm can be made 50% or more.

Further, when the p-side contact electrode 41 is made of a metal such as Ru, Rh, or an alloy containing these as main components, NiAu, and Mg, the transmittance for the ultraviolet light having a wavelength of 280 nm can be made 30% or more by setting the thickness of the p-side contact electrode 41 to 10 nm or less. When the thickness of the p-side contact electrode 41 is 4 nm or less, the transmittance for the ultraviolet light having a wavelength of 280 nm can be 50% or more.

The p-side electrode pad 42 is provided in contact with the p-side contact electrode 41. The p-side electrode pad 42 is made of Ti/Ni/Au/Al, Ti/Pt/Au/Al, or the like. A thickness of the p-side electrode pad 42 is 300 nm to 600 nm. The p-side electrode pad 42 is formed to be thicker than the p-side contact electrode 41. In other words, the p-side contact electrode 41 is formed to be thinner than the p-side electrode pad 42. The p-side electrode pad 42 can be formed together with the n-side electrode pad 32.

The protective layer 50 is provided so as to cover an upper surface side of the light emitting element 5 except for a part of the n-side electrode pad 32 and a part of the p-side electrode pad 42. The protective layer 50 is made of an insulating material, and is formed of, for example, SiO₂ and SiN.

The reflective layer 60 is provided on a back surface of the element substrate 10 (the lower surface in FIG. 2, the surface opposite to a light extraction side). The reflective layer 60 may not be provided. The reflective layer 60 reflects the ultraviolet light emitted from the active layer 22 in a light extraction direction. The reflective layer 60 may have a single-layer structure or a multi-layer structure.

### 3. Experiments

### Experiment 1

In Experiment 1, a test piece 1 in which a layer made of AlCu corresponding to the bonding wire 6 was formed on the principal surface of a sapphire substrate was used, and as a comparative example, and a test piece 2 in which a layer made of Al corresponding to the bonding wire 6 was formed on the principal surface of a sapphire substrate was used to measure the reflectance of ultraviolet light with an emission wavelength of 200 nm to 400 nm. In the test piece 1, Cu is set to 0.5 wt %.

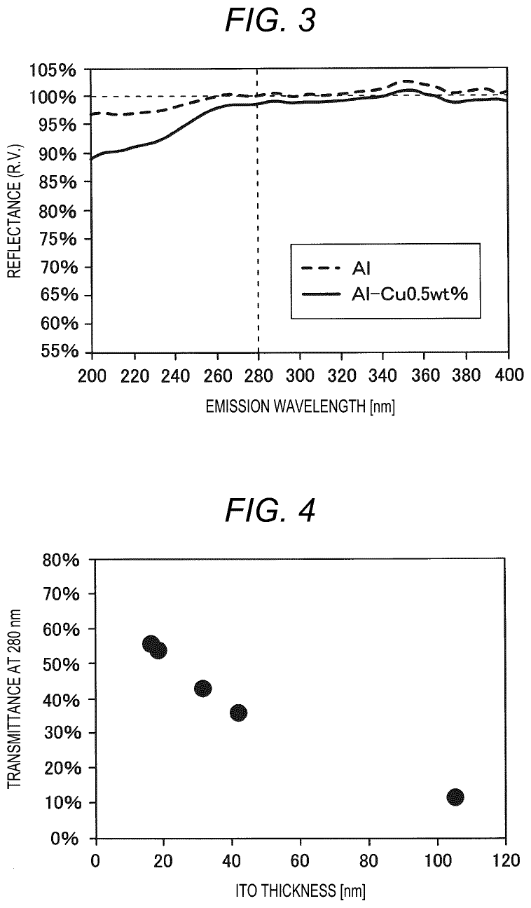

In FIG. 3, the reflectance of the test piece 2 at an emission wavelength of 280 nm is set to 100%. As shown in FIG. 3, the reflectance of the test piece 1 is inferior to that of the test piece 2 in the emission wavelength range of 200 nm to 400 nm, but is approximately the same. In particular, the reflectance of the test piece 1 is closer to that of the test piece 2 in the emission wavelength range of 260 nm to 400 nm. From this, it is understood that by using AlCu for the bonding wire 6, it is possible to obtain a reflectance equivalent to that of Al.

### Experiment 2

In Experiment 2, a test piece 3 in which ITO corresponding to the p-side contact electrode 41 was formed on the principal surface of a sapphire substrate was used to measure the transmittance of ultraviolet light having a wavelength of 280 nm. The test pieces 3 had five different ITO thicknesses of 16 nm, 18 nm, 32 nm, 42 nm, and 105 nm.

The transmittance was 56%, 54%, 42%, 36%, and 12% for ITO thicknesses of 16 nm, 18 nm, 32 nm, 42 nm, and 105 nm, respectively.

As shown in FIG. 4, based on the results of Experiment 2, it is possible to obtain a transmittance of 35% or more through ITO by setting the thickness of ITO to 40 nm or less. Further, by making the thickness of the ITO 20 nm or less, it is possible to obtain a transmittance of 50% or more through the ITO.

### 4. Effects

According to the light emitting device 1 of the present embodiment, the bonding wire 6 is made only of an alloy containing Al as a main component and Cu, it is possible to obtain a reflectance as high as that of Al. Accordingly, high light extraction efficiency of ultraviolet light can be obtained. Further, by forming the bonding wire 6 from the above material, electromigration resistance can be improved and breakage failures and the like can be reduce as compared to the case where Al is used, resulting in an improved life span and increased reliability. In this case, the bonding wire 6 may include an alloy containing Al as a main component and containing Cu, and may also include a layer made of another material.

In addition to the alloy containing Al as a main component and containing Cu, the following materials can also be used as the bonding wire 6, providing the same effect. That is, the same effect can be obtained when the bonding wire 6 is made of at least one selected from the group consisting of an alloy containing Mg as a main component and containing Cu, Mg, and an alloy containing Mg. In this case, the bonding wire 6 includes the above metal, and may include a layer made of another material.

Further, the same effect can be obtained when the bonding wire 6 includes a first layer made of Cu or an alloy containing Cu, and a second layer made of one selected from the group consisting of Al, an alloy containing Al, Mg, and an alloy containing Mg. In this case, the bonding wire 6 may include only the first layer and the second layer, or may include a layer made of another material in addition to the first layer and the second layer.

Accordingly, the light emitting device 1 has a structure that is excellent in resistance to electromigration while maintaining a high light extraction efficiency by using the bonding wire 6 made of a material having high reflectance.

### REFERENCE SIGNS LIST

1 light emitting device
2 mounting substrate
2a mounting surface
4 submount
5 light emitting element
6 bonding wire
10 element substrate
20 semiconductor layer
21 n-type layer
22 active layer
23 p-type layer
30 n-side electrode
40 p-side electrode
41 p-side contact electrode
42 p-side electrode pad

What is claimed is:

1. A light emitting device comprising:
a light emitting element containing a group III nitride and configured to emit ultraviolet light; and
a bonding wire electrically connected to the light emitting element,
wherein the bonding wire
contains at least one selected from the group consisting of: an alloy containing Al as a main component and containing Cu; an alloy containing Mg as a main component and containing Cu; Mg; and an alloy containing Mg, or
includes a first layer containing Cu or an alloy containing Cu, and a second layer containing one selected from the group consisting of: Al; an alloy containing Al; Mg; and an alloy containing Mg.

2. The light emitting device according to claim 1,
wherein, of the bonding wire, a wire electrically connected to a p-side electrode of the light emitting element
contains at least one selected from the group consisting of: an alloy containing Al as a main component and containing Cu; an alloy containing Mg as a main component and containing Cu; Mg; and an alloy containing Mg, or
includes a first layer containing Cu or an alloy containing Cu, and a second layer containing one selected from the group consisting of: Al; an alloy containing Al; Mg; and an alloy containing Mg.

3. The light emitting device according to claim 1,
wherein the light emitting element includes an electrode pad, and
wherein the bonding wire is bonded to the electrode pad of the light emitting element.

4. The light emitting device according to claim 2,
wherein the light emitting element includes an electrode pad, and
wherein the bonding wire is bonded to the electrode pad of the light emitting element.

5. The light emitting device according to claim 3, further comprising:
a mounting substrate having a mounting surface,
wherein the light emitting element is mounted on the mounting surface of the mounting substrate and is a face-up type having the electrode pad on a surface, opposite to the mounting surface, of the mounting substrate, and
wherein the bonding wire has one end bonded to the electrode pad of the light emitting element, and other end bonded to the mounting substrate.

6. The light emitting device according to claim 4, further comprising:
a mounting substrate having a mounting surface,
wherein the light emitting element is mounted on the mounting surface of the mounting substrate and is a face-up type having the electrode pad on a surface, opposite to the mounting surface, of the mounting substrate, and
wherein the bonding wire has one end bonded to the electrode pad of the light emitting element, and other end bonded to the mounting substrate.
